(19) United States
(12) Patent Application Publication
(10) Pub. No.: US 2014/0120719 A1
(43) Pub. Date: May 1, 2014

(54) METHOD OF MANUFACTURING A SEMICONDUCTOR DEVICE

(71) Applicants: Changliang Qin, Beijing (CN); Huaxiang Yin, Beijing (CN)

(72) Inventors: Changliang Qin, Beijing (CN); Huaxiang Yin, Beijing (CN)

(21) Appl. No.: 13/812,505

(22) PCT Filed: Oct. 12, 2012
(86) PCT No.: PCT/CN12/01380

§ 371 Date: Jan. 26, 2013

(30) Foreign Application Priority Data
Aug. 9, 2012 (CN) 201210283268.1

(51) Int. Cl. H01L 21/3213

(52) U.S. Cl. CPC H01L 21/32139
USPC 438/669

(57) ABSTRACT

The present invention relates to a method of manufacturing a semiconductor device for improving the spacer mask. In the present invention, a barrier layer and a sacrificial layer are formed, and the portions of the upper part of the spacer whose left and right sides differ greatly are ground away to leave the portion similar to a rectangle at the bottom of the spacer, which is used as the mask to perform the subsequent spacer masking technology. Thus the undesirable influences to the subsequent etching caused by the asymmetric profile of the spacer can be reduced as much as possible.

### CROSS REFERENCE

This application is a National Phase application of, and claims priority to, PCT Application No. PCT/CN2012/001380, filed on Oct. 12 , 2012, entitled ‘METHOD OF MANUFACTURING A SEMICONDUCTOR DEVICE’, which claimed priority to Chinese Application No. CN 201210283268.1, filed on Aug. 9, 2012. Both the PCT Application and Chinese Application are incorporated herein by reference in their entireties.

### FIELD OF THE INVENTION

The present invention relates to the field of manufacture of a semiconductor integrated circuit, in particular to a transistor manufacturing method that uses a sacrificial layer and a barrier layer to improve the spacer patterning technology.

### BACKGROUND OF THE INVENTION

Ever since the semiconductor integrated circuit technology has entered into the technical node of a feature size of 90 nm, it becomes increasingly challenging to maintain or improve the transistor performance. In order to conform to the Moore's Law, it is required that the device feature size should be reduced continuously, but the conventional 193 nm photolithography has almost reached its limit, while other technologies like EUV and electron beam are still far from business application.

As a low-cost and easily applicable photolithography technology, the spacer patterning technology is considered adoptable for the next generation feature size. Referring to FIGS. 1 and 2, a material bar 20, e.g. a gate line, is formed first on a substrate 10. The width of the material bar 20 is, for example, the feature size of photolithography; next, a spacer material layer is deposited and a back-etch is performed, thus spacers 30 are formed at both sides of the material bar 20, wherein the outer side of the spacer 30 has an arc line, and the bottom width of the spacer 30 can be smaller than the feature size by etching control; and then, the material bar 20 is removed while the spacers 30 are left on the substrate, and a line whose width is smaller than the feature size can be obtained by etching with the spacers 30 used as masks.

However, the spacer patterning technology also has a distinct deficiency, namely, the profile of the spacer is not laterally symmetric, thus the shape formed by the subsequent etching is not laterally symmetric. The spacer has an arc side, while the shape of the bottom of the spacer is similar to a rectangle, so if only this rectangle part is used as a mask to perform the spacer patterning technology, it is possible to achieve a better shape by etching. Hence, there is a need for a new transistor manufacturing method to solve the above problem so as to better ensure the effect of the spacer patterning technology.

### SUMMARY OF THE INVENTION

The present invention provides a transistor manufacturing method that improves the spacer patterning technology by means of a technology similar to the gate-last process, which avoids the deficiency in the existing spacer patterning technology.

According to one aspect of the present invention, the present invention provides a method of manufacturing a semiconductor device for improving the spacer mask in the spacer patterning technology, characterized in that the method comprises the following steps:
providing a semiconductor substrate, forming a barrier layer and a sacrificial layer in sequence on the semiconductor substrate and patterning the barrier layer and the sacrificial layer;
depositing a spacer material layer;
back-etching the spacer material layer anisotropically leaving only the spacer material layer located on the side faces of the barrier layer and the sacrificial layer so as to form a spacer;
depositing an interlayer dielectric, wherein the interlayer dielectric completely covers the barrier layer, the sacrificial layer and the spacer; performing a CMP process to remove the interlayer dielectric, the sacrificial layer and the spacer above the upper surface of the barrier layer with the CMP process terminated at the upper surface of the barrier layer, so that the remaining spacer forms a spacer mask; and
removing the barrier layer and the remaining interlayer dielectric leaving only the spacer mask on the semiconductor substrate.

In the present invention, the material of the barrier layer is SiO₂.

In the present invention, the material of the sacrificial layer is one of polysilicon, amorphous silicon and photoresist.

In the present invention, the material of the spacer is Si₃N₄.

In the present invention, the CMP process includes two phases: the first phase is to perform a CMP processing on the interlayer dielectric until reaching the upper surface of the sacrificial layer; and the second phase is to perform a CMP processing on the sacrificial layer and the upper part of the spacer until reaching the upper surface of the barrier layer.

In the present invention, the spacer mask is used for forming a pattern whose line size is smaller than the feature size.

The present invention has the following advantages: in the process of forming the spacer mask in the present invention, a barrier layer and a sacrificial layer are formed, and the portions of the upper part of the spacer whose left and right sides differ greatly are ground away to leave the portion similar to a rectangle at the bottom of the spacer, which is used as the mask to perform the subsequent spacer masking technology. Since the spacer mask of the present invention has a profile similar to a rectangle, compared to spacers in the prior art whose side faces are large arcs, the present invention can obtain a more consistent masking effect and reduce the uncontrollability of the subsequent mask etching process caused by irregularity of the spacer shape, so that the line with a sub-F size obtained through the mask can better meet the design requirements, thereby guaranteeing the performance of the transistor.

### BRIEF DESCRIPTION OF THE DRAWINGS

FIGS. 1-2 show the spacer patterning technology of the prior art; and

FIGS. 3-7 are schematic drawings of the flows of the manufacturing method in the present invention.

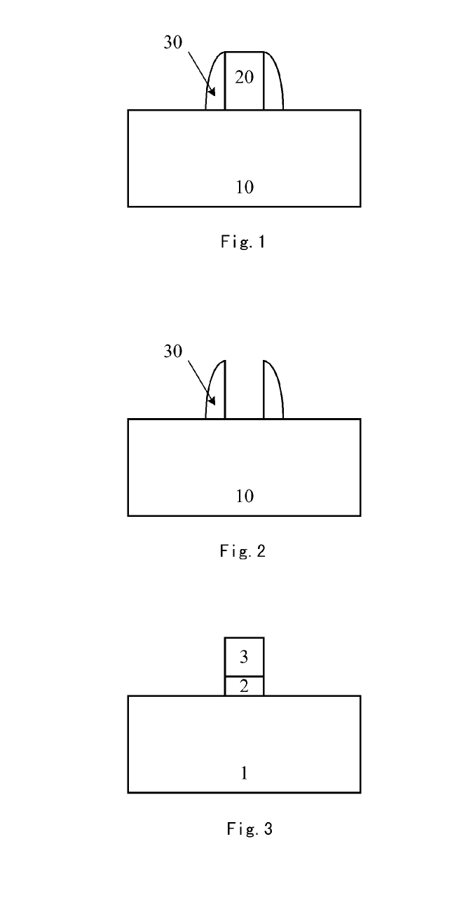

### DETAILED DESCRIPTION OF THE PREFERRED EMBODIMENTS

The present invention is described below through the specific embodiments shown in the figures, but it shall be understood that these descriptions are exemplary and are not intended to limit the scope of the present invention. In addition, in the text below, descriptions about the known structures and techniques are omitted to avoid unnecessarily confusing the concept of the present invention.

The present invention provides a semiconductor device manufacturing method, in particular relates to improving the spacer patterning technology by means of a sacrificial layer and a barrier layer, which avoids the deficiency in the existing spacer patterning technology. Now the semiconductor device manufacturing method provided by the present invention will be described in details with reference to FIGS. 3-7.

First, referring to FIG. 3, a barrier material layer and a sacrificial material layer (not shown) are deposited in sequence on a semiconductor substrate 1 and are patterned to form a barrier layer 2 and a sacrificial layer 3. If the feature size of the photolithography process is F, then the line widths of the barrier layer 2 and the sacrificial layer 3 can be F or any appropriate values greater than F. Wherein, the material of the barrier layer 2 is SiO₂, and the material of the sacrificial layer 3 is polysilicon or amorphous silicon. In another embodiment, the material of the sacrificial layer 3 can be a photoresist, namely, the barrier material layer 2 is patterned by etching with a patterned photoresist layer and then the photoresist layer is retained as the sacrificial layer 3.

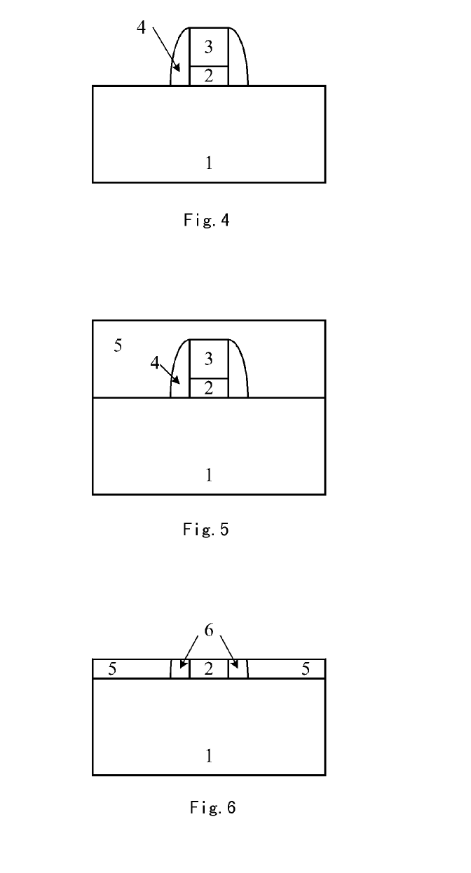

Next, referring to FIG. 4, a spacer 4 is formed. The forming steps specifically includes: depositing a spacer material layer (not shown), e.g. Si₃N₄, on the substrate 1, wherein a deposition process of good conformity is used so that the barrier layer 2 and the sacrificial layer 3 can be covered by the spacer material layer with a preset thickness; and then removing the spacer material layer on a horizontal surface in the figure by means of an anisotropic back-etch process, so that the spacer material layer is left only on the sidewalls of the barrier layer 2 and the sacrificial layer 3 to form a spacer 4, that is, the spacer 4 surrounding the side faces of the barrier layer 2 and the sacrificial layer 3. Due to the anisotropic back-etch process, the outer side of the spacer 4 formed by this step, i.e. the side far away from the barrier layer 2 and the sacrificial layer 3, has an arc shape instead of being completely vertical to the surface of the substrate, besides, due to the back-etch process, the upper part of the arc shape has a larger radian, while the lower part thereof is approximately vertical to the substrate. Therefore, the spacer 4 has a smaller width at the top and a larger width at the bottom. By controlling the thickness of the spacer material layer as well as the parameters of the back-etch process, the bottom width of the spacer 4, i.e. the maximum width thereof, can be smaller than the feature size F.

Subsequently, an interlayer dielectric 5 is deposited, as shown in FIG. 5. The interlayer dielectric 5 has a thickness sufficient to cover and surround the barrier layer 2, the sacrificial layer 3 and the spacer 4. The interlayer dielectric 5 fills between respective structures, e.g. between a plurality of separate barrier layers 2, sacrificial layers 3 and spacers 4, for securing the structures and for buffering in the subsequent CMP process. The material of the interlayer dielectric 5 is preferably TEOS.

Next, the CMP (Chemical Mechanical Polishing) process is performed, as shown in FIG. 6. the CMP process includes two phases: in the first phase, the CMP processing is performed on the interlayer dielectric 5 until reaching the upper surface of the sacrificial layer 3; and then, in the second phase, the CMP processing is performed on the sacrificial layer 3 and the upper part of the spacer 4 until reaching the upper surface of the barrier layer 2, or a preset over-CMP processing is performed after reaching the upper surface of the barrier layer 2, and the CMP in the second step also removes a part of the interlayer dielectric 5 having a corresponding thickness at the same time. Thus after the two phases of CMP processing, a profile as shown in FIG. 6 is obtained, wherein, the upper surfaces of the remaining interlayer dielectric 5 and the remaining spacer 4 are flush with the upper surface of the barrier layer 2. The remaining spacer 4 is the lower part 6 of the spacer 4, and the outer side of the lower part 6 of the spacer has a small radian, and the line of the spacer is approximately vertical to the substrate surface, namely, the profile of the lower part 6 of the spacer is close to a rectangle, so the lower part 6 of the spacer can be used as a spacer mask afterwards. According to the method of the present invention, the height of the remaining spacer after the CMP process, i.e. the height of the lower part 6 of the spacer, depends on the thickness of the barrier layer 2 formed in FIG. 3, and the thickness of the barrier layer 2 as well as the parameters of the CMP process can be adjusted according to the practical needs to obtain the lower part 6 of the spacer that is similar to a rectangle and has a desired height.

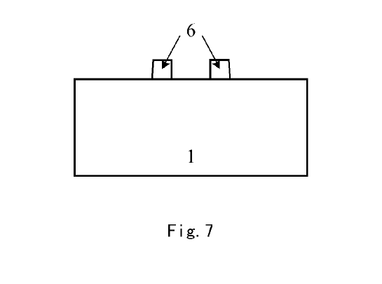

Then, referring to FIG. 7, the barrier layer 2 and the interlayer dielectric 5 are removed leaving only the lower part 6 of the spacer on substrate 1 so that the remaining lower part 6 can be used as a mask in the subsequent spacer masking technique. Since the width of the lower part 6 of the spacer may be smaller than the feature size F, when using it as the mask, line patterns having a size smaller than F can be obtained. Because the lower part 6 of the spacer that is used as the mask in the present invention has a profile similar to a rectangle, compared to the spacer in the prior art whose side faces are large arcs, the spacer mask of the present invention can obtain a more consistent masking effect and reduce the uncontrollability of the subsequent mask etching process caused by irregularity of the spacer shape, so that the line with a sub-F size obtained through the mask can better meet the design requirements, thereby guaranteeing the performance of the transistor.

The semiconductor manufacturing method that improves the spacer patterning technology has been described in details in the above text. In the process of forming the spacer mask in the present invention, a barrier layer and a sacrificial layer are formed, and by using CMP process, the portions of the upper part of the spacer whose left and right sides differ greatly are ground away to leave the portion similar to a rectangle at the bottom of the spacer, which is used as the mask to perform the subsequent spacer masking technology. Thus the undesirable influences to the subsequent etching caused by the asymmetric profile of the spacer can be reduced as much as possible.

The present invention is described in the above text in conjunction with specific embodiments, but these embodiments are merely illustrative and they do not intend to limit the scope of the present invention. The scope of the present invention is defined by the appended claims and the equivalents thereof. Those skilled in the art can make various replacements and modifications without departing from the scope of the present invention, so these replacements and modifications shall fall within the scope of the present invention.

What is claimed is:

1. A method of manufacturing a semiconductor device for improving the spacer mask in the spacer patterning technology, characterized in that the method comprises the following steps:
providing a semiconductor substrate, forming a barrier layer and a sacrificial layer in sequence on the semiconductor substrate and patterning the barrier layer and the sacrificial layer;
depositing a spacer material layer;
back-etching the spacer material layer anisotropically leaving only the spacer material layer located on the side faces of the barrier layer and the sacrificial layer so as to form a spacer;
depositing an interlayer dielectric, wherein the interlayer dielectric completely covers the barrier layer, the sacrificial layer and the spacer;
performing a CMP process to remove the interlayer dielectric, the sacrificial layer and the spacer above the upper surface of the barrier layer with the CMP process terminated at the upper surface of the barrier layer, so that the remaining spacer forms a spacer mask; and
removing the barrier layer and the remaining interlayer dielectric leaving only the spacer mask on the semiconductor substrate.

2. The method according to claim 1, characterized in that the material of the barrier layer is SiO₂.

3. The method according to claim 1, characterized in that the material of the sacrificial layer is one of polysilicon, amorphous silicon and photoresist.

4. The method according to claim 1, characterized in that the material of the spacer is Si₃N₄.

5. The method according to claim 1, characterized in that the CMP process includes two phases: the first phase is to perform a CMP processing on the interlayer dielectric until reaching the upper surface of the sacrificial layer; and the second phase is to perform a CMP processing on the sacrificial layer and the upper part of the spacer until reaching the upper surface of the barrier layer.

6. The method according to claim 1, characterized in that the spacer mask is used for forming a pattern whose line size is smaller than the feature size.
